(19) United States
(12) Patent Application Publication
(10) Pub. No.: US 2009/0096557 A1
(43) Pub. Date: Apr. 16, 2009

(54) Variable Inductance Applying Device Using Variable Capacitor and Variable Frequency Generating Device Thereof

(75) Inventors: Yun-seong Eo, Suwon-si (KR); Kwang-du Lee, Suwon-si (KR); Heung-bae Lee, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 12/333,540

(22) Filed: Dec. 12, 2008

Related U.S. Application Data
(63) Continuation of application No. 11/360,525, filed on Feb. 24, 2006.
Application No. 11/360,525 is a continuation of application No. 10/375,053, filed on Feb. 28, 2003, now abandoned.

(30) Foreign Application Priority Data
Feb. 28, 2005 (KR) 2005-0016802

(51) Int. Cl. H03J 3/22

(52) U.S. Cl. 334/66; 331/181

(57) ABSTRACT

Disclosed is a variable inductance applying device using a variable capacitor, and a variable frequency generating device thereof. The variable inductance applying device includes: a first inductor whose both terminals are connected to an inductance applying terminal applying inductance to an external circuit; a second inductor inductively coupled to the first inductor; and a variable capacitor connected to both terminals of the second inductor, which varies inductance from the inductance applying terminal by changing capacitance. Therefore, the inductance to be applied to the external circuit can be varied by changing the capacitance of the variable capacitor. Since the variable capacitor rarely contains a resistance component, energy loss due to the resistance component hardly occurs. As a result, the variable inductance applying device has a high value of Q.

### CROSS-REFERENCE TO RELATED APPLICATIONS

This application is a continuation of U.S. application Ser. No. 10/375,053 filed Feb. 24, 2006, the disclosure of which is incorporated herein by reference in its entirety. This application claims priority from Korean Patent Application No. 2005-16802, filed Feb. 28, 2005.

### BACKGROUND OF THE INVENTION

1. Field of the Invention

The present invention relates in general to a variable inductance applying device and a variable frequency generating device using the same. More specifically, the present invention relates to a variable inductance applying device applying inductance to a circuit in need of variable inductance, and a variable frequency generating thereof.

2. Description of the Related Art

For communication equipment to work, diverse ranges of frequencies are required. To this end, communication equipment must have a frequency generating and processing (amplification for example) device, which is realized by using a crystal or LC resonance circuit.

The LC resonance circuit generates frequencies that change according to an inductance L and a capacitance C. Thus, by changing the L or C, various ranges of frequencies can be generated. In most cases, C of the LC resonance circuit is changed to vary frequencies. In such case, however, the variable range is very narrow. Therefore, changing the frequency through changing C gives rise to problems especially in a multi-band communication system requiring a broad variable frequency range.

For the above-described reason, it has been suggested to change L of the LC resonance circuit to change frequency. This is realized by selecting a variable inductance applying device, and not by setting L of the LC resonance circuit. The following explains a variable inductance applying device.

FIG. 1A illustrates a circuit diagram of a variable inductance applying device according to a related art. The variable inductance applying device of FIG. 1A applies variable inductance to a resonance circuit through the a-b terminal. As can be seen in the drawing, the variable inductance applying device consists of two inductors L₁, L₂, and a Metal Oxide Semiconductor MOS transistor M.

In this variable inductance applying device, two different inductances are applied to the resonance circuit through the a-b terminal, according to the switching operation of the switching element M. In detail, when M is ‘On’, the inductance applied from the a-b terminal is L₁, whereas when M is ‘Off’, the inductance applied from the a-b terminal is (L₁+L₂).

As shown in FIG. 1A, a plurality of different inductances can be applied to the resonance circuit by using a plurality of inductors and a switching element. However, since a switching element such as the MOS transistor M includes a resistance component, it causes energy loss.

Moreover, according to FIG. 1B which illustrates a life-size variable inductance applying device of FIG. 1A, the plurality of inductors L₁ and L₂ are located at different planes from each other. This results in an increase in the size of the resonance circuit.

As an attempt to solve the size problem, a variable inductance applying device shown in FIG. 2 was suggested. The size of the variable inductance applying device was reduced by placing one (20) of the plurality of inductors (10) on the outer ring. This variable inductance applying device also uses a switching element S/W 30, thereby allowing different inductances to be applied through the a-b terminal, according to the ‘On/Off’ operation of the S/W 30.

However, the variable inductance applying device as shown in FIG. 2 does not address the energy loss problem caused by the resistance component in the switching element 30.

### SUMMARY OF THE INVENTION

It is, therefore, an aspect of the present invention to provide a variable inductance applying device with a high value of quality factor Q, capable of applying inductance to a circuit in need of variable inductance with a low energy loss, and a variable frequency generating and processing device thereof.

An aspect of the present invention is to provide a variable inductance applying device, including: a first inductor whose both terminals are connected to an inductance applying terminal applying inductance to an external circuit; a second inductor inductively coupled to the first inductor; and a variable capacitor connected to both terminals of the second inductor, which varies inductance from the inductance applying terminal by changing capacitance.

It is preferable, but not necessary that the variable capacitor is either a junction varactor or a MOS (Metal Oxide Semiconductor) varactor.

Also, the second inductor is located in one of an upper, a lower or an outside area of the first inductor.

Also, the number of turns of the second inductor is plural.

Another aspect of the present invention is to provide a frequency generating and processing device, including: a first inductor whose both terminals are connected to an inductance applying terminal which applies inductance; a second inductor inductively coupled to the first inductor; a variable capacitor connected to both terminals of the second inductor, which varies inductance from the inductance applying terminal by changing the capacitance; and a resonance circuit generating a resonance frequency by using the inductance applied from the inductance applying terminal and self inductance.

It is preferable, but not necessary that the variable capacitor is either a junction varactor or a MOS (Metal Oxide Semiconductor) varactor.

Still another aspect of the present invention is to provide a communication device, including: a first inductor whose both terminals are connected to an inductance applying terminal which applies inductance; a second inductor inductively coupled to the first inductor; a variable capacitor connected to both terminals of the second inductor, which varies inductance from the inductance applying terminal by changing the capacitance; a resonance circuit generating and amplifying a resonance frequency by using the inductance applied from the inductance applying terminal and self inductance; and a modem performing at least one of modulation or demodulation by using the resonance frequency generated in the resonance circuit.

Again, it is preferable, but not necessary that the variable capacitor is either a junction varactor or a MOS (Metal Oxide Semiconductor) varactor.

### BRIEF DESCRIPTION OF THE DRAWINGS

The above aspects and features of the present invention will be more apparent by describing certain exemplary embodiments of the present invention with reference to the accompanying drawings, in which:

FIG. 1A is a circuit diagram of a variable inductance applying device according to a related art;

FIG. 1B illustrates the actual variable inductance applying device of FIG. 1A;

FIG. 2 illustrates another example of a variable inductance applying device according to a related art;

FIG. 3 is a circuit diagram of a variable inductance applying device using a variable capacitor, in accordance with one exemplary embodiment of the present invention; and

FIG. 4 illustrates the exemplary embodiment of the variable inductance applying device of FIG. 3.

FIG. 5 is a diagram of a variable frequency generating device, formed by combining a variable inductance applying device and a resonance circuit, in accordance with one exemplary embodiment of the present invention.

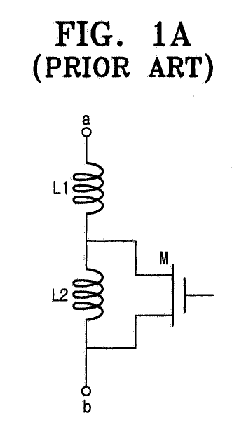

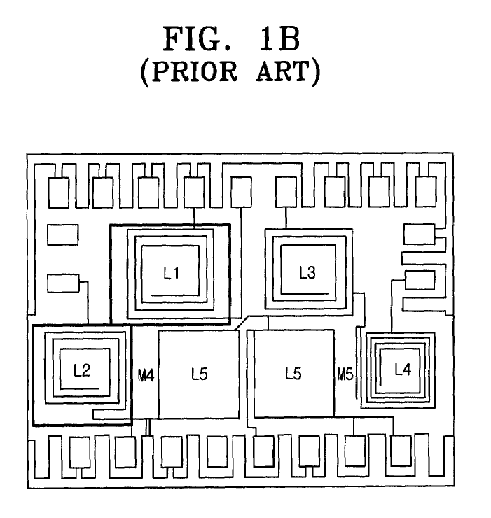

### DETAILED DESCRIPTION OF THE EXEMPLARY EMBODIMENTS

An exemplary embodiment of the present invention will be described herein below with reference to the accompanying drawings.

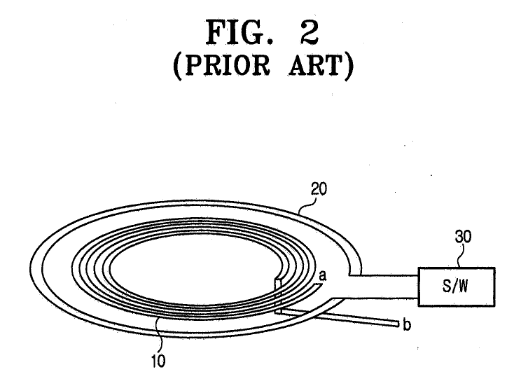

FIG. 3 is a circuit diagram of a variable inductance applying device, in accordance with one exemplary embodiment of the present invention. The variable inductance applying device applies inductance to a resonance circuit through an inductance applying terminal a-b. Referring to FIG. 3, the variable inductance applying device includes a main inductor L₁, a sub inductor L₂, and a variable capacitor Cᵥ.

Both terminals of the main inductor L₁ are connected to the inductance applying terminal a-b, whereas both terminals of the sub inductor L₂ are connected to the variable capacitor Cᵥ (to be described). Further, the main inductor L₁ and the sub inductor L₂ are inductively coupled to each other, and the mutual inductance between the two is labeled ‘M’.

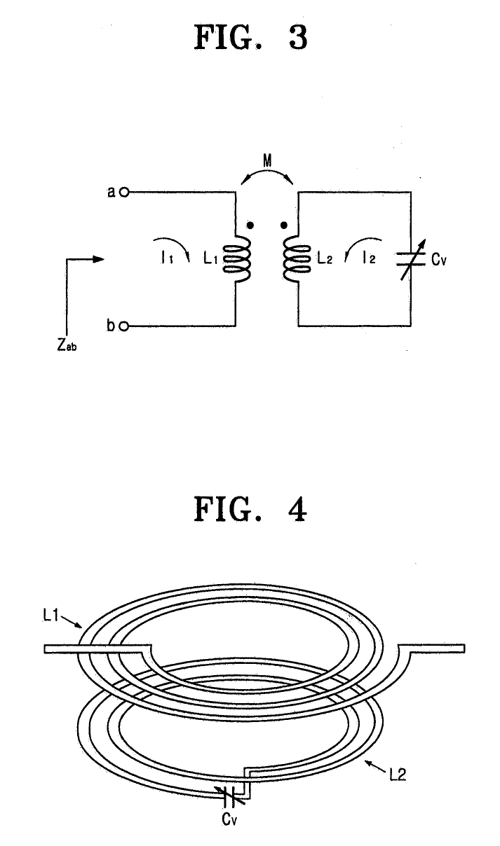

There is no limitation on the arrangement or configuration of the main inductor L₁ and the sub inductor L₂. For instance, as shown in FIG. 4, the sub inductor L₂ may be positioned below the main inductor L₁. Moreover, it is also possible to put the sub inductor L₂ on the upper portion or on the outer ring of the main inductor L₁.

The number of turns in the main inductor L₁ and the sub inductor L₂ can be set arbitrarily. However, it is preferable, but not necessary, to set the number of turns in the sub inductor L₂ high in order to increase the variable range of inductance applied by the variable inductance applying device. For example, in FIG. 4, the number of turns in the sub inductor L₂ is ‘2’. Therefore, to expand the variable range of the inductance applied by the variable inductance applying device, the number of turns in the sub inductor L₂ should be increased.

The variable capacitor Cᵥ is connected to both terminals of the sub inductor L₂. The variable capacitor Cᵥ is an element whose capacitance changes by an external control signal. As for the variable capacitor Cᵥ, a junction varactor, a MOS (Metal Oxide Semiconductor) varactor, etc., can be used.

The variable capacitor Cᵥ varies inductance applied to a resonance circuit from the inductance applying terminal a-b by changing its capacitance. More details are provided below.

Inductance applied to a resonance circuit from the inductance applying terminal a-b can be analyzed through input impedance Z_{ab} of the inductance applying terminal a-b. The input impedance Z_{ab} can be obtained as follows. The input impedance Z_{ab} is calculated based on a loop equation of a loop including the main inductor L₁, and a loop equation of a loop including the sub inductor L₂. Those two loop equations are expressed in Equation 1 below.

$${V}_{ab} = jω {L}_{1} {I}_{1} + jω {MI}_{2} \\ 0 = jω {MI}_{1} + ( j ω {L}_{2} + \frac{1}{j ω {C}_{v}} ) {I}_{2} \qquad [ Equation 1 ]$$

Here, V_{ab} corresponds to a voltage at the inductance applying terminal a-b.

I₂ can be expressed in terms of I₁ as shown in Equation 2.

$${I}_{2} = \frac{- jω M}{j ω {L}_{2} + \frac{1}{jω {C}_{v}}} {I}_{1} = \frac{{ω}^{2} {MC}_{v}}{1 - {ω}^{2} {L}_{2} {C}_{v}} {I}_{1} \qquad [ Equation 2 ]$$

Substituting Equation 2 into the first part in Equation 1 yields Equation 3 for V_{ab} as follows:

$${V}_{ab} = jω {L}_{1} {I}_{1} + jω \frac{{ω}^{2} {M}^{2} {C}_{v}}{1 - {ω}^{2} {L}_{2} {C}_{v}} {I}_{1} \qquad [ Equation 3 ]$$

Dividing both sides of Equation 3 by I₁ yields input impedance Z_{ab} of the inductance applying terminal a-b as follows:

$${Z}_{ab} = \frac{{V}_{ab}}{{I}_{1}} = jω {L}_{1} + jω \frac{{ω}^{2} {M}^{2} {C}_{v}}{1 - {ω}^{2} {L}_{2} {C}_{v}} \qquad [ Equation 4 ]$$

According to Equation 4, the input impedance Z_{ab} of the inductance applying terminal a-b has only the inductance component. This inductance component is inductance L_{ab} that is applied to a resonance circuit from the inductance applying terminal a-b. The inductance L_{ab} can be expressed as follows:

$${L}_{ab} = {L}_{1} + \frac{{ω}^{2} {M}^{2} {C}_{v}}{1 - {ω}^{2} {L}_{2} {C}_{v}} \qquad [ Equation 5 ]$$

According to Equation 5, the inductance L_{ab} applied from the inductance applying terminal a-b to a resonance circuit changes depending on Cᵥ. In other words, if Cᵥ is increased, L_{ab} is increased as well. Likewise, if Cᵥ is decreased, L_{ab} is decreased.

So far, it has been explained that the inductance L_{ab} applied from the inductance applying terminal a-b to a resonance circuit can be varied by changing Cᵥ.

The variable capacitor Cᵥ can imitate the functions of a switching element that can vary the inductance L_{ab} applied from the inductance applying terminal a-b to a resonance circuit according to an external control signal.

However, unlike a switching element such as a transistor or a diode, the variable capacitor Cᵥ rarely contains a resistance component. Therefore, energy loss caused by the resistance component hardly occurs in the capacitor Cᵥ. That is, the variable inductance applying device of the present invention has a high value of Q.

As discussed above, it has been explained that the variable inductance applying device varies the inductance L_{ab} that is applied from the inductance applying terminal a-b to a resonance circuit, by changing the capacitance of the variable capacitor Cᵥ.

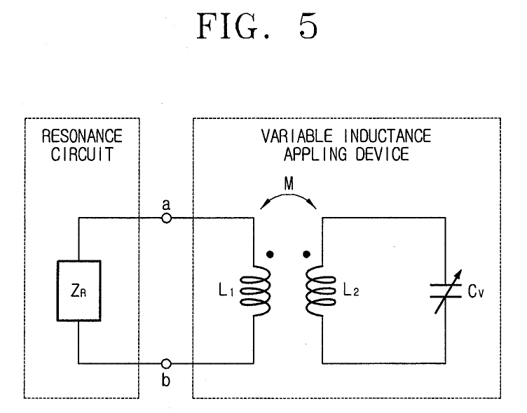

Meanwhile, a variable frequency generating and processing (amplification for example) device can be implemented by combining the variable inductance applying device with a resonance circuit generating a resonance frequency by using the self capacitance and the inductance L_{ab} that is applied from the inductance applying terminal a-b, as shown in FIG. 5. By adopting the variable inductance applying device, the variable frequency generating and processing device can minimize energy loss in the variable frequency generation.

Furthermore, a transmitter or a receiver can be implemented by combining the variable frequency generating and processing device with a modem performing modulation or demodulation. Again, by adopting the variable frequency generating and processing device, the transmitter or the receiver can minimize energy loss in the modulation or the demodulation.

The variable inductance applying device according to the present invention can be utilized to apply variable inductance to an external circuit by changing capacitance of the variable capacitor. Unlike the switching element such as a transistor or a diode, the variable capacitor rarely contains a resistance component. Therefore, energy loss due to the resistance component hardly occurs, and the variable inductance applying device has a high value of Q.

Furthermore, by utilizing the variable inductance applying device, a variable frequency generating and processing device, a transmitter, a receiver, etc., with a high energy efficiency may be realized.

The foregoing embodiments and advantages are merely exemplary in nature and are not to be construed as limiting the present invention. The present teaching can be readily applied to other types of apparatuses. Also, the description of the exemplary embodiments of the present invention is intended to be illustrative, and therefore it does not limit the scope of the claims. Alternatives, modifications, and variations will be readily apparent to those skilled in the art.

What is claimed is:

1. A variable inductance applying device, comprising:
a first inductor connected to an inductance applying terminal;
a second inductor coupled to the first inductor; and
a capacitor having a variable capacitance, the capacitor being connected to the second inductor to change inductance of the inductance applying terminal as the capacitance changes.

2. The variable inductance applying device according to claim 1, wherein the second inductor is not electrically connected to the first inductor.

3. A communication device, comprising:
a first inductor included in the communication device and connected to an inductance applying terminal;
a second inductor included in the communication device and coupled to the first inductor; and
a capacitor included in the communication device and having a variable capacitance, the capacitor being connected to the second inductor to change inductance of the inductance applying terminal as the capacitance changes.

4. The communication device according to claim 3, wherein the second inductor is not electrically connected to the first inductor.

5. The communication device according to claim 3, wherein the first inductor, the second inductor, and the capacitor are included in a transmitter.

6. The communication device according to claim 3, wherein the first inductor, the second inductor, and the capacitor are included in a receiver.
